(19) United States
(12) Patent Application Publication
(10) Pub. No.: US 2025/0275439 A1
(43) Pub. Date: Aug. 28, 2025

(54) Display Device

(71) Applicant: LG Display Co., Ltd., Seoul (KR)

(72) Inventors: Jae-Choul Yu, Paju-si (KR); Jeong-Oh Kim, Paju-si (KR); Myung-Jae Yoo, Paju-si (KR); Geum-Young Lee, Paju-si (KR); Se-Yeon Jung, Paju-si (KR)

(21) Appl. No.: 18/929,101

(22) Filed: Oct. 28, 2024

(30) Foreign Application Priority Data
Feb. 23, 2024 (KR) 10-2024-0026491

(51) Int. Cl. H10K 59/80

(52) U.S. Cl. CPC H10K 59/879; H10K 59/80515; H10K 59/80517

(57) ABSTRACT

A display device includes: a substrate having a plurality of subpixels; a transistor in each of the plurality of subpixels; a planarizing layer on the transistor; a micro pattern on the planarizing layer in each of the plurality of subpixels; a cushion layer on the micro pattern; and a light emitting diode on the planarizing layer.

### CROSS REFERENCE TO RELATED APPLICATION

The present application claims the priority benefit of Republic of Korea Patent Application No. 10-2024-0026491 filed on Feb. 23, 2024, which is hereby incorporated by reference in its entirety.

### BACKGROUND

### Technical Field

The present disclosure relates to a display device, and more particularly, to a display device where a bezel is reduced.

### Discussion of the Related Art

Recently, as multimedia is progressed, an importance of a display device increases. As a result, a flat panel display such as a liquid crystal display (LCD), a plasma display panel (PDP) and an organic light emitting diode (OLED) display has been commercialized.

Among the flat panel displays, the organic light emitting diode display has been widely used because of its advantages such as a high response speed, a high luminance and a wide viewing angle.

However, since about 70% or more of a light is disappeared in the organic light emitting diode display, the organic light emitting diode display has a disadvantage such as a light efficiency of about 25%.

### SUMMARY

Accordingly, the present disclosure is directed to a display device that substantially obviates one or more of the problems due to limitations and disadvantages of the related art.

An object of the present disclosure is to provide a display device where a light efficiency is improved.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate including a plurality of subpixels; a transistor in each of the plurality of subpixels; a planarizing layer on the transistor; a micro pattern on the planarizing layer in each of the plurality of subpixels; a cushion layer on the micro pattern; and a light emitting diode on the planarizing layer.

In another embodiment, a display device including: a substrate including a plurality of subpixels; a transistor in each of the plurality of subpixels; a planarizing layer on the transistor; and a light emitting diode on the planarizing layer, the light emitting diode including an anode, an emitting layer and a cathode, wherein a top surface of the anode is formed as a curved surface.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of a display device according to a first embodiment of the present disclosure;

FIG. 3 is a circuit diagram showing a subpixel of a display device according to a first embodiment of the present disclosure;

FIG. 4 is a plan view showing a pixel of a display device according to a first embodiment of the present disclosure;

FIG. 5A is a cross-sectional view showing a display device without a micro pattern according to a comparison example;

FIG. 5B is a cross-sectional view showing a display device with a micro pattern according to a first embodiment of the present disclosure;

FIG. 6 is a cross-sectional view showing a display device according to a first embodiment of the present disclosure;

FIG. 7 is a cross-sectional view showing a display device according to a second embodiment of the present disclosure;

FIG. 8A is a cross-sectional view showing a micro pattern and a light emitting diode of a display device according to a first embodiment of the present disclosure;

FIG. 8B is a cross-sectional view showing a micro pattern and a light emitting diode of a display device according to a second embodiment of the present disclosure;

FIG. 9 is a cross-sectional view showing a display device according to a third embodiment of the present disclosure;

FIG. 10A is a cross-sectional view showing a micro pattern and a light emitting diode of a display device according to a first embodiment of the present disclosure;

FIG. 10B is a cross-sectional view showing a micro pattern and a light emitting diode of a display device according to a third embodiment of the present disclosure; and

FIGS. 11A to 11F are cross-sectional views showing a method of fabricating a display device according to a third embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

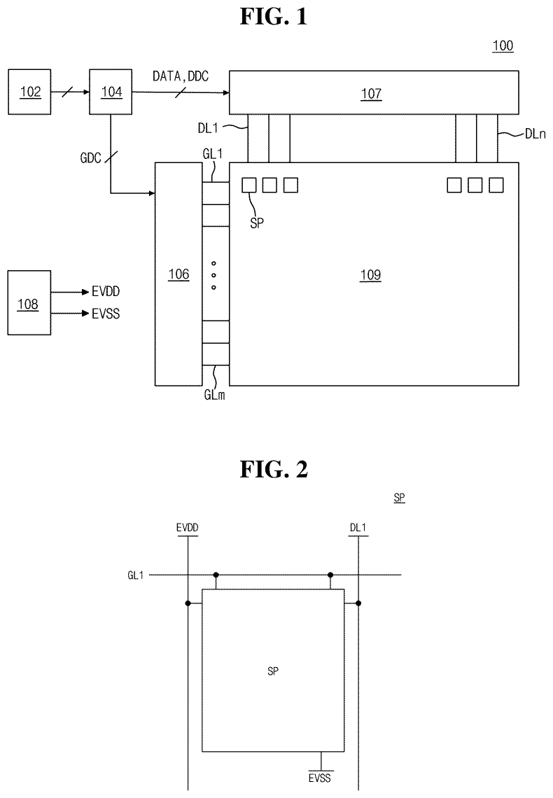

FIG. 1 is a view showing a display device according to a first embodiment of the present disclosure, and FIG. 2 is a view showing a subpixel of a display device according to a first embodiment of the present disclosure.

In FIG. 1, a display device 100 according to a first embodiment of the present disclosure includes an image processing unit 102, a timing controlling unit 104, a gate driving unit 106, a data driving unit 107, a power supplying unit 108 and a display panel 109.

The image processing unit 102 (e.g., a circuit) outputs a plurality of timing signals for various units as well as an image signal supplied from an exterior. For example, the plurality of timing signals may include a data enable signal, a vertical synchronization signal, a horizontal synchronization signal and a clock signal.

The timing controlling unit 104 receives the image signal and the plurality of timing signals from the image processing unit 102. The timing controlling unit 104 generates an image data DATA, a gate control signal GDC and a data control signal DDC using the image signal and the plurality of timing signals. The timing controlling unit 104 transmits the gate control signal GDC to the gate driving unit 106 and transmits the image data and the data control signal DDC to the data driving unit 107.

The gate driving unit 106 (e.g., a circuit) generates a gate signal (a gate voltage, a scan signal) using the gate control signal GDC transmitted from the timing controlling unit 104 and applies the gate signal to a plurality of gate lines GL1 to GLm of the display panel 109. Although the gate driving unit 106 may be formed as an integrated circuit (IC), it is not limited thereto.

The gate driving unit 106 may have a gate-in-panel (GIP) type where the gate driving unit 106 is disposed on a substrate of the display panel 109.

The data driving unit 107 (e.g., a circuit) generates a data signal (a data voltage) using the data control signal DDC and the image data DATA transmitted from the timing controlling unit 104 and applies the data signal to a plurality of data lines DL1 to DLn of the display panel 109. The data driving unit 107 samples and latches the image data DATA of a digital type to output the data signal of an analog type based on a gamma reference voltage. Although the data driving unit 107 may be formed as an integrated circuit (IC), it is not limited thereto.

The power supplying unit 108 (e.g., a circuit) outputs a high-level voltage Vdd and a low level voltage Vss. The power supplying unit 108 supplies the high-level voltage Vdd to the display panel 109 through a first power line EVDD and supplies the low level voltage Vss to the display panel 109 through a second power line EVSS. In addition, the high-level voltage Vdd and the low level voltage Vss of the power supplying part 108 may be supplied to the gate driving unit 106 or the data driving unit 107 for driving.

The display panel 109 displays an image using the gate signal of the gate driving unit 106, the data signal of the data driving unit 107 and the high-level voltage Vdd and the low level voltage Vss of the power supplying unit 108.

The display panel 109 includes a plurality of subpixels SP, a plurality of gate lines GL1 to GLm and a plurality of data lines DL1 to DLn. The plurality of subpixels SP may include red, green and blue subpixels SP or white, red, green and blue subpixels SP. The white, red, green and blue subpixels SP may have the same area as each other or may have a different area from each other.

In FIG. 2, a single subpixel SP may be connected to the gate line GL1, the data line DL1, the first power line EVDD and the second power line EVSS. A driving method as well as a number of a transistor and a capacitor of the subpixel SP may be determined according to a structure of a subpixel circuit. For example, the subpixel SP may have a structure of 2T1C including two transistors and one capacitor. In another embodiment, the subpixel SP may have a structure of one of 3T1C, 4T1C, 5T1C, 6TIC, 7T1C, 3T2C, 4T2C, 5T2C, 6T2C, 7T2C and 8T2C.

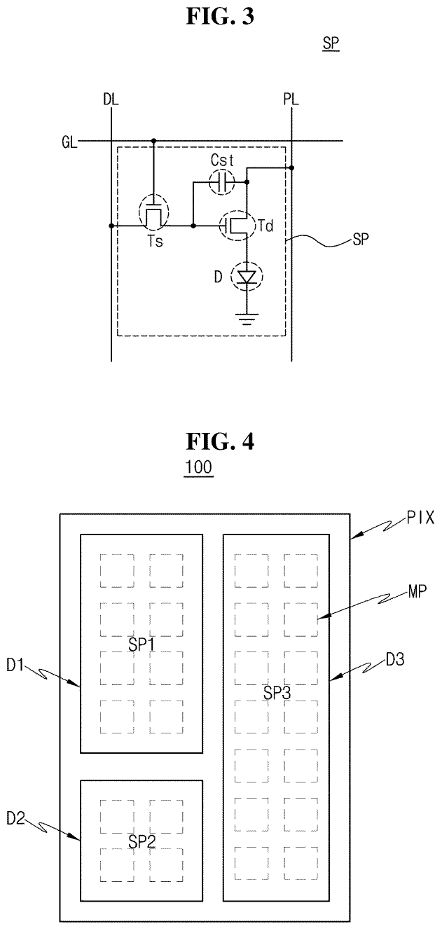

FIG. 3 is a circuit diagram showing a subpixel of a display device according to a first embodiment of the present disclosure.

In FIG. 3, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Td and Td and one capacitor Cst in an embodiment of FIG. 3, the subpixel SP may include three or more transistors and two or more capacitors in another embodiment.

FIG. 4 is a plan view showing a pixel of a display device according to a first embodiment of the present disclosure.

In FIG. 4, the display device 100 according to a first embodiment of the present disclosure includes a plurality of pixels PIX, and each of the plurality of pixels PIX may include a plurality of subpixels SP1, SP2 and SP3. For example, the first subpixel SP1 may be a green subpixel emitting a green colored light, the second subpixel SP2 may be a red subpixel emitting a red colored light, and the third subpixel SP3 may be a blue subpixel emitting a blue colored light. In another embodiment, the first subpixel SP1 may be a red subpixel or a blue subpixel, the second subpixel SP2 may be a green subpixel or a blue subpixel, and the third subpixel SP3 may be a green subpixel or a red subpixel.

The pixel PIX has an S-stripe type where the third subpixel SP3 is arranged along a vertical direction and the first and second subpixels SP1 and SP2 are arranged along a horizontal direction in an embodiment of FIG. 4. The pixel PIX may have a stripe type, a delta type or a diamond type in another embodiment.

An area of the first subpixel SP1 is greater than an area of the second subpixel SP2 and smaller than an area of the third subpixel SP3 in an embodiment of FIG. 4. The first, second and third subpixels SP1, SP2 and SP3 may have the same area as each other, or an area of the first subpixel SP1 may be greater than an area of the third subpixel SP3 and may be smaller than an area of the second subpixel SP2 in another embodiment. The first, second and third subpixels SP1, SP2 and SP3 may have various areas as necessary.

First, second and third light emitting diodes D1, D2 and D3 may be disposed in the first, second and third subpixels SP1, SP2 and SP3, respectively. For example, the first light emitting diode D1 may be a green organic light emitting diode emitting a green colored light, the second light emitting diode D2 may be a red organic light emitting diode emitting a red colored light, and the third light emitting diode D3 may be a blue organic light emitting diode emitting a blue colored light. In another embodiment, the first light emitting diode D1 may be a red organic light emitting diode or a blue organic light emitting diode, the second light emitting diode D2 may be a green organic light emitting diode or a blue organic light emitting diode, and the third light emitting diode D3 may be a green organic light emitting diode or a red organic light emitting diode.

Although not shown, each of the first, second and third light emitting diodes D1, D2 and D3 may include a first electrode, a second electrode and an emitting layer between the first and second electrodes. The first electrode may be an anode. The first electrode is disposed in each of the first, second and third subpixels SP1, SP2 and SP3, and the first electrodes in the adjacent subpixels are electrically separated from each other. The data signal may be applied to the first electrode from the data driving unit 107.

A micro pattern MP is disposed in each of the first, second and third subpixels SP1, SP2 and SP3. One or more micro patterns MP may be disposed in each of the first, second and third subpixels SP1, SP2 and SP3. Although the micro pattern MP has a square shape in an embodiment of FIG. 4, the micro pattern MP may have one of a circular shape, an elliptical shape and a polygonal shape such as a rectangular shape, a triangular shape and a pentagonal shape.

The micro patterns MP in the first, second and third subpixels SP1, SP2 and SP3 have the same shape and the same area as each other in an embodiment of FIG. 4. The micro patterns MP in the first, second and third subpixels SP1, SP2 and SP3 have the different shape and the different area from each other in another embodiment.

The micro pattern MP is formed to improve a light efficiency of the first, second and third light emitting diodes D1, D2 and D3.

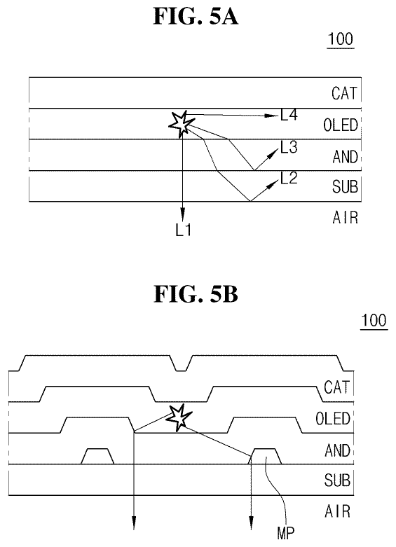

FIG. 5A is a cross-sectional view showing a display device without a micro pattern according to a comparison example, and FIG. 5B is a cross-sectional view showing a display device with a micro pattern according to a first embodiment of the present disclosure.

In FIG. 5A, the display device 100 without a micro pattern MP according to a comparison example includes a substrate SUB, an anode AND, an organic emitting layer OLED and a cathode CAT. When a voltage is applied to the anode AND and the cathode CAT, an electron is injected into the organic emitting layer OLED from the cathode CAT and a hole is injected into the organic emitting layer OLED. As a result, an exciton is generated in the organic emitting layer OLED, and a light corresponding to an energy difference between a lowest unoccupied molecular orbital (LUMO) and a highest occupied molecular orbital (HOMO) of the organic emitting layer OLED is emitted according to decay of the exciton.

When the display device 100 has a bottom emission type where a light is downwardly emitted through the substrate SUB, the light of the organic emitting layer OLED be emitted to an exterior through the anode AND and the substrate SUB.

In the display device 100 of a bottom emission type, when the light of the organic emitting layer OLED passes through the anode AND and the substrate SUB, a light having an incident angle equal to or greater than a critical angle is totally reflected at an interface between the anode AND and the substrate SUB and at an interface between the substrate SUB and an air AIR.

For example, about 10% of the light of the organic emitting layer OLED may be totally reflected at the interface between the anode AND and the substrate SUB, and about 30% of the light of the organic emitting layer OLED may be totally reflected at the interface between the substrate SUB and the air AIR.

Further, a surface plasmon polariton (SPP) mode is generated at an interface between a metallic material layer and an organic material layer, and about 40% of the light of the organic emitting layer OLED is lost at the interface between a metallic material layer and an organic material layer due to a free electron of the metallic material layer in the SPP mode.

In the display device 100 without a micro pattern MP, about 80% of the light of the organic emitting layer OLED is not emitted to an exterior due to the total reflection or the SPP mode, and only about 20% of the light of the organic emitting layer OLED is emitted to an exterior. As a result, the display device 100 without a micro pattern MP has a relatively low light efficiency.

In FIG. 5B, the display device 100 with a micro pattern MP according to a first embodiment of the present disclosure includes a substrate SUB, a micro pattern MP, an anode AND, an organic emitting layer OLED, and a cathode CAT.

In the display device 100 of a bottom emission type, the incident angle of the light of the organic emitting layer OLED at the interface between the anode AND and the substrate SUB and the incident angle of the light of the organic emitting layer OLED at the interface between the substrate SUB and the air AIR are changed due to the micro pattern MP. As a result, the light totally reflected at the interface between the anode AND and the substrate SUB and at the interface between the substrate SUB and the air AIR are at least reduced or minimized.

Further, since a surface of the anode AND and a surface of the cathode CAT are not flat but uneven, the SPP mode at the interface between the metallic material layer and the organic material layer is reduced or removed. As a result, the loss of the light of the organic emitting layer OLED at the interface between the metallic material layer and the organic material layer is at least reduced or minimized.

In the display device 100 with the micro pattern MP, the total reflection of the light at the interface between the anode AND and the substrate SUB and at the interface between the substrate SUB and the air AIR is at least reduced or minimized, and the loss of the light at the interface between the metallic material layer and the organic material layer is reduced or minimized. As a result, a light extraction efficiency of the organic emitting layer OLED is improved or maximized.

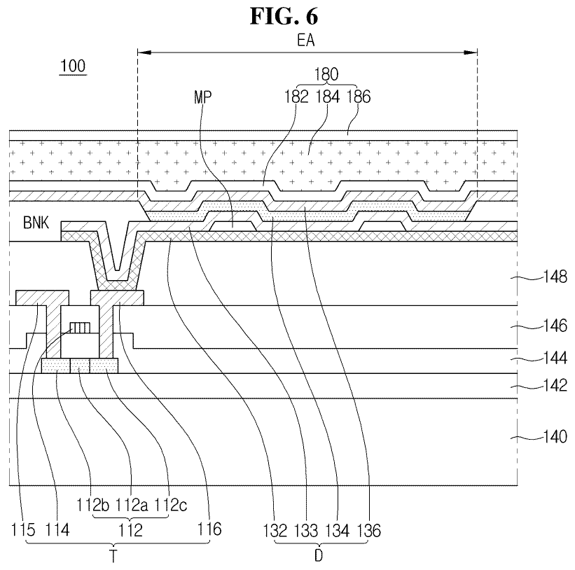

FIG. 6 is a cross-sectional view showing a display device according to a first embodiment of the present disclosure. Although the display device 100 includes a plurality of subpixels, only one subpixel is shown in FIG. 6 for illustration's convenience.

In FIG. 6, a buffer layer 142 is disposed on a substrate 140. The substrate 140 may include a hard material such as a glass or a soft material such as a plastic material. The plastic material may include polyimide (PI), polymethylmethacrylate (PMMA), polyethylene terephthalate (PET), polyether sulfone (PES) and polycarbonate (PC), and it is not limited thereto.

For example, when the substrate 140 includes polyimide, the substrate 140 may include a plurality of polyimide layers. Further, an inorganic layer may be disposed between the polyimide layers, and it is not limited thereto.

The buffer layer 142 may be disposed on the entire substrate 140 to increase an adhesive strength between layers and the substrate 140 and to block an alkali ingredient released from the substrate 140. Further, the buffer layer 142 may delay diffusion of a moisture or an oxygen permeating the substrate 140.

The buffer layer 142 may have a single layer or a multiple layer of an inorganic insulating material such as silicon nitride (SiNx) and silicon oxide (SiOx). When the buffer layer 142 has a multiple layer, a layer of silicon nitride (SiNx) and a layer of and silicon oxide (SiOx) may be alternated with each other. The buffer layer 142 may be omitted based on a kind and a material of the substrate 140 and a structure and a type of the thin film transistor.

A thin film transistor T is disposed on the buffer layer 142. Although a driving thin film transistor among a plurality of thin film transistors is shown in FIG. 6, the other thin film transistors such as a switching thin film transistor may be disposed on the buffer layer 142. Further, although the thin film transistor T has a top gate structure in FIG. 6, the thin film transistor T may have the other structure such as a bottom gate structure.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 may include a polycrystalline semiconductor material. For example, the polycrystalline semiconductor material may include polycrystalline silicon having a relatively high mobility, and it is not limited thereto.

The semiconductor layer 112 may include an oxide semiconductor material. For example, the oxide semiconductor material may include one of indium gallium zinc oxide (IGZO), indium zinc oxide (IZO), indium gallium tin oxide (IGTO) and indium gallium oxide (IGO), and it is not limited thereto. The semiconductor layer 112 has a channel region 112a of an intrinsic material at a central portion thereof and source and drain regions 112b and 112c of a doped material at both sides of the channel region 112a.

The gate insulating layer 144 may have a single layer or a multiple layer of an inorganic insulating material such as silicon nitride (SiNx) and silicon oxide (SiOx), and it is not limited thereto.

The gate electrode 114 includes a metallic material. For example, the gate electrode 114 may have a single layer or a multiple layer of one of molybdenum (Mo), aluminum (Al), chromium (Cr), gold (Au), silver (Ag), tungsten (W), titanium (Ti), nickel (Ni), neodymium (Nd), copper (Cu) and an alloy thereof, and it is not limited thereto.

The interlayer insulating layer 146 may have a single layer or a multiple layer of an organic insulating material such as photoacryl or an inorganic insulating material such as silicon nitride (SiNx) and silicon oxide (SiOx). Further, the interlayer insulating layer 146 may have a multiple layer of an organic layer and an inorganic layer, and it is not limited thereto.

The source and drain electrodes 115 and 116 may have a single layer or a multiple layer of one of molybdenum (Mo), aluminum (Al), chromium (Cr), gold (Au), silver (Ag), tungsten (W), titanium (Ti), nickel (Ni), neodymium (Nd), copper (Cu) and an alloy thereof, and it is not limited thereto. The source and drain electrodes 115 and 116 may be connected to the source and drain regions 112b and 112c, respectively, of the semiconductor layer 112 through contact holes in the gate insulating layer 144 and the interlayer insulating layer 146.

Although not shown, a bottom shielding metal layer may be disposed on the substrate 140 under the semiconductor layer 112. The bottom shielding metal layer may minimize a back-channel phenomenon generated due to charges trapped in the substrate 140 to prevent a residual image or deterioration of a transistor. The bottom shielding metal layer may have a single layer or a multiple layer of one of titanium (Ti), molybdenum (Mo) and an alloy thereof, and it is not limited thereto.

A planarizing layer 148 is disposed on the thin film transistor T over the substrate 140. The planarizing layer 148 may include an organic insulating material such as photoacryl, and it is not limited thereto. The planarizing layer 148 may have a multiple layer of an inorganic layer and an organic layer.

A light emitting diode D is disposed on the planarizing layer 148. The light emitting diode D includes a first electrode 132, a second electrode 133, an emitting layer 134, and a third electrode 136.

The first electrode 132 is disposed on the planarizing layer 148 and is electrically connected to the drain electrode 116 of the thin film transistor T through a contact hole in the planarizing layer 148. The first electrode 132 may include a transparent conductive material such as indium tin oxide (ITO) and indium zinc oxide (IZO).

The second electrode 133 is disposed on the first electrode 133. The second electrode 133 may include at least one of silver (Ag), aluminum (Al), gold (Au), molybdenum (Mo), tungsten (W), chromium (Cr) and an alloy thereof. Alternatively, the second electrode 133 may include a transparent conductive material such as indium tin oxide (ITO) and indium zinc oxide (IZO).

When the display device 100 has a top emission type, the second electrode 133 may further include an opaque conductive material for using the second electrode 133 as a reflective layer. When the display device 100 has a bottom emission type, the second electrode 133 may include a transparent conductive material such as indium tin oxide (ITO) and indium zinc oxide (IZO).

The first electrode 132 and the second electrode 133 may have the same area as each other or a different area from each other. Since the first electrode 132 is electrically connected to the drain electrode 116 of the thin film transistor T and the second electrode 133 on the first electrode 132 is electrically connected to the first electrode 132, a voltage may be applied to the first electrode 132 and the second electrode 133 through the thin film transistor T. As a result, the first electrode 132 and the second electrode 133 may function as an anode of the light emitting diode D.

A bank layer BNK is disposed in a boundary region of each subpixel on the planarizing layer 148. The bank layer BNK may be a kind of wall defining the subpixel. The bank layer BNK may prevent or at least reduce a mixture of lights of various colors emitted from adjacent subpixels SP.

The bank layer BNK may include at least one of an inorganic insulating material such as silicon nitride (SiNx) and silicon oxide (SiNx), an organic insulating material such as benzocyclobutene (BCB), acrylic resin, epoxy resin, phenolic resin, polyamide resin and polyimide resin and a photosensitive material including a black pigment, and it is not limited thereto.

Although the bank layer BNK is disposed on a boundary portion of the second electrode 133 in an embodiment of FIG. 6, the first electrode 132 and the second electrode 133 may extend over a slanting surface of the bank layer BNK in another embodiment.

The bank layer BNK has a matrix shape throughout the entire display device 100, and a region surrounded by the bank layer BNK and emitting a light to display an image may be defined as an emission area EA.

The micro pattern MP is disposed between the first electrode 132 and the second electrode 133. Although the micro pattern MP may include an inorganic insulating material such as silicon nitride (SiNx) and silicon oxide (SiOx), it is not limited thereto. Although the micro pattern MP may have a single layer, it is not limited thereto. The micro pattern MP may have a slanting side surface.

The micro pattern MP may be formed by depositing and etching the inorganic insulating material. While the inorganic insulating material is etched, the first electrode 132 functions as a blocking layer to prevent the planarizing layer 148 from being damaged.

As a result, the second electrode 133 may function as an anode, and the first electrode 132 may function as a protecting layer.

The emitting layer 134 may be disposed on a top surface of the second electrode 133, a side surface of the bank layer BNK and a top surface of the bank layer BNK. The emitting layer 134 may include a red emitting layer emitting a red colored light in a red subpixel SP, a green emitting layer emitting a green colored light in a green subpixel SP and a blue emitting layer emitting a blue colored light in a blue subpixel SP. For example, the emitting layer 134 may include an organic emitting layer, an inorganic emitting layer, a nano-sized material layer, a quantum dot layer, an emitting layer of a micro light emitting diode (LED) and an emitting layer of a mini-LED, and it is not limited thereto.

The emitting layer 134 may include an emitting material layer, an electron injecting layer injecting an electron, a hole injecting layer injecting a hole, an electron transporting layer transporting an electron, a hole blocking layer blocking a hole, an electron blocking layer blocking an electron and a hole transporting layer transporting a hole, and it is not limited thereto.

The third electrode 136 is disposed on the emitting layer 134. The third electrode 136 may have a single layer or a multiple layer of a metallic material or an alloy of metallic materials. Alternatively, the third electrode 136 may include a transparent conductive material such as indium tin oxide (ITO) and indium zinc oxide (IZO), and it is not limited thereto.

When the display device 100 has a top emission type, the third electrode 136 may include a half transmissive conductive material transmitting a light. For example, the third electrode 136 may include at least one of alloys of LiF/Al, CsF/Al, Mg: Ag, Ca/Ag, Ca: Ag, LiF/Mg: Ag, LiF/Ca/Ag and LiF/Ca: Ag.

When the display device 100 has a bottom emission type, the third electrode 136 may include an opaque conductive material for using the third electrode 136 as a reflective layer. For example, the third electrode 136 may include at least one of silver (Ag), aluminum (Al), gold (Au), molybdenum (Mo), tungsten (W), chromium (Cr) and an alloy thereof.

The light emitting diode D may have a tandem structure. The tandem structure may include a plurality of emitting layers and a charge generating layer between adjacent two of the plurality of emitting layers. The charge generating layer for adjusting a charge balance of the plurality of organic layers may have a multiple layer including first and second charge generating layers. The charge generating layer may include a negative (N) type charge generating layer and a positive (P) type charge generating layer. For example, the charge generating layer may include an organic layer doped with an alkali metal such as lithium (Li), sodium (Na), potassium (K) and cesium (Cs) or an alkali earth metal such as magnesium (Mg), strontium (Sr), barium (Ba) and radium (Ra), and it is not limited thereto.

An encapsulating layer 180 is disposed on the light emitting diode D. When the light emitting diode D is exposed to a moisture or oxygen, a pixel shrinkage phenomenon where an emission area EA is reduced or deterioration of a dark spot in the emission area EA may occur. Further, moisture or oxygen may oxidize the electrode of a metallic material. The encapsulating layer 180 blocks permeation of moisture or oxygen from an exterior to prevent deterioration of the light emitting diode D and the electrodes.

Although the encapsulating layer 180 has a triple layer of first, second and third encapsulating layers 182, 184 and 186 in a first embodiment, the encapsulating layer 180 may have a double layer or a quadruple layer in another embodiment.

The first and third encapsulating layer 182 and 186 may have a single layer or a multiple layer of an inorganic material such as silicon oxide (SiOx), silicon oxynitride (SiON) and silicon nitride (SiNx), and it is not limited thereto. The second encapsulating layer 184 may include an organic material such as acryl resin, epoxy resin, polyimide, polyethylene and silicon oxycarbide (SiOC), and it is not limited thereto. The third encapsulating layer 186 may include a face seal metal, and it is not limited thereto.

Although not shown, the display device 100 may include a touch unit. The touch unit may be disposed in the display area to sense a touch input. For example, the touch unit may sense an external touch information using a finger of a user or a touch pen.

In the display device 100 according a first embodiment of the present disclosure, since the micro pattern MP is disposed in the emission area EA, the light loss due to the total reflection and the SPP mode in the display device 100 is reduced or minimized, and the light efficiency of the display device 100 increases or is maximized.

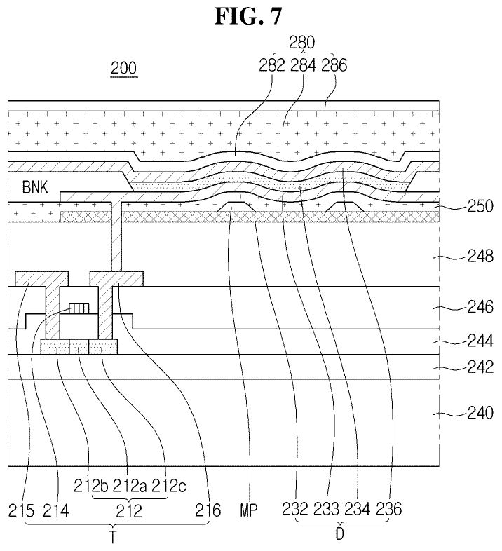

FIG. 7 is a cross-sectional view showing a display device according to a second embodiment of the present disclosure. Illustration on a part the same as that of a first embodiment will be omitted, and a part different from that of a first embodiment will be illustrated.

In FIG. 7, a thin film transistor T and a light emitting diode D are disposed on a substrate 240.

The thin film transistor T includes a semiconductor layer 212 on a buffer layer 242, a gate insulating layer 244 on the semiconductor layer 212, a gate electrode 214 on the gate insulating layer 244, an interlayer insulating layer 246 on the gate electrode 214 and source and drain electrodes 215 and 216 on the interlayer insulating layer 246.

The light emitting diode D includes a first electrode 232, a second electrode 233, an emitting layer 234, and a third electrode 236. The first electrode 232 and the second electrode 233 may function as an anode of the light emitting diode D, and the third electrode 236 may function as a cathode of the light emitting diode D. Alternatively, the first electrode 232 may function as a protecting layer, the second electrode 233 may function as an anode, and the third electrode 236 may function as a cathode.

A bank layer BNK is disposed on the planarizing layer 248 and a boundary portion of the second electrode 233. At least one micro pattern MP is disposed between the first electrode 232 and the second electrode 233 in an emission area EA surrounded by the bank layer BNK.

The micro pattern MP changes an incident angle of a light of the emitting layer 234 at interfaces among the second electrode 233, the first electrode 232 and the planarizing layer 248 to at least reduce or minimize a total reflection and reduces a flatness of the interfaces among the second electrode 233, the first electrode 232 and the planarizing layer 248 to prevent a surface plasmon polariton (SPP) mode.

A cushion layer 250 is disposed on the first electrode 233. The cushion layer 250 is disposed between the first electrode 232 and the second electrode 233, and the micro pattern MP is disposed between the first electrode 232 and the cushion layer 250.

The cushion layer 250 may include an inorganic material or an organic material having a refractive index similar to a refractive index of the micro pattern MP. For example, the cushion layer 250 may include an inorganic material such as silicon nitride (SiNx) and silicon oxide (SiOx).

Since the micro pattern MP and the cushion layer 250 include materials having similar refractive indexes, a refraction of a light at an interface between the micro pattern MP and the cushion layer 250 is prevented. The micro pattern MP changes a structure of layers and an incident angle of a light at interfaces among the layers to at least reduce or minimize a total reflection in the display device 200. Since the micro pattern MP and the cushion layer 250 include materials having similar refractive indexes, the micro pattern MP of a second embodiment of FIG. 7 may have the same shape as the micro pattern MP of a first embodiment of FIG. 6. As a result, a design of the micro pattern MP may be simplified.

In another embodiment, the micro pattern MP and the cushion layer 250 may include materials having different refractive indexes. Since the light is refracted at the interface between the micro pattern MP and the cushion layer 250 in another embodiment, the micro pattern MP of another embodiment may have the different shape (e.g., an area of the micro pattern MP, an angle of a side surface of the micro pattern MP) from the micro pattern MP of a first embodiment of FIG. 6.

Since the cushion layer 250 is disposed between the micro pattern MP and the second electrode 233 to alleviate a step difference of the micro pattern MP, a non-uniform thickness of the second electrode 233 due to the step difference of the micro pattern MP is prevented or at least reduced. As a result, the cushion layer 250 may have a thickness to alleviate the step difference of the micro pattern MP.

An emitting layer 234 and a third electrode 236 are sequentially disposed on the second electrode 233 to constitute a light emitting diode D, and an encapsulating layer 280 is disposed on the light emitting diode D.

In the display device 200, since the step difference of the micro pattern MP is alleviated due to the cushion layer 250, deterioration of a luminance is reduced or prevented.

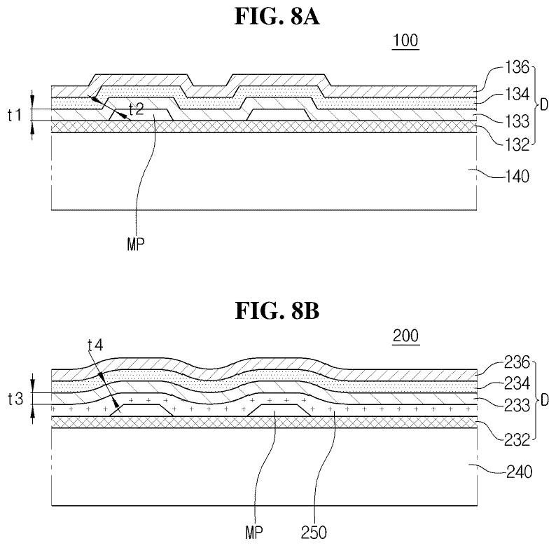

FIG. 8A is a cross-sectional view showing a micro pattern and a light emitting diode of a display device according to a first embodiment of the present disclosure, and FIG. 8B is a cross-sectional view showing a micro pattern and a light emitting diode of a display device according to a second embodiment of the present disclosure.

In FIG. 8A, since the second electrode 133 is disposed directly on the side surface and the top surface of the micro pattern MP in the display device 100 according to a first embodiment of the present disclosure, a first thickness t1 of the second electrode 133 on the first electrode 132 is different from a second thickness t2 of the second electrode 133 on the slating side surface of the micro pattern MP (t1≠t2).

In the display device 100 according to a first embodiment of the present disclosure, a thickness of the second electrode 133 is not uniform throughout the entire substrate 140 to have a deviation, and a current supplied to the second electrode 133 has a different amount according to a position due to the deviation. As a result, the display device 100 according to a first embodiment of the present disclosure has a different luminance according to the position.

In FIG. 8B, the cushion layer 250 is disposed to cover the micro pattern MP and the second electrode 233 is disposed on the micro pattern MP in the display device 200 according to a second embodiment of the present disclosure. Since the cushion layer 250 alleviates the step difference of the micro pattern MP, a third thickness t3 of the second electrode 233 over the first electrode 232 is similar to a fourth thickness t4 of the second electrode 233 over the side surface of the micro pattern MP (t3≈t4).

Accordingly, in the display device 200 according to a second embodiment of the present disclosure, since a non-uniform current due to the thickness deviation of the second electrode 233 is not generated, a non-uniform luminance of the display device 200 according to the position is prevented.

Specifically, in FIGS. 8A and 8B, an angle of the side surface of the micro pattern MP with respect to the bottom surface of the micro pattern MP of the display device 200 according to a second embodiment of the present disclosure may be smaller than an angle of the side surface of the micro pattern MP with respect to the bottom surface of the micro pattern MP of the display device 100 according to a first embodiment of the present disclosure. Further, a width of the slanting side surface of the micro pattern MP of the display device 200 may be greater than a width of the slanting side surface of the micro pattern MP of the display device 100.

Since the top surface of the cushion layer 250 has a round shape similar to a curved surface, the second electrode 233 has a round shape similar to a curved surface. As a result, the step difference of the micro pattern MP is reduced or removed, and the second electrode 233 may have a uniform thickness throughout the entire substrate 240.

The second electrode 233 of the light emitting diode D may be electrically connected to the drain electrode 216 of the thin film transistor T through a contact hole in the planarizing layer 248 and the cushion layer 250.

In the display device 200 according a second embodiment of the present disclosure, since the micro pattern MP is disposed in the emission area EA, the light efficiency of the display device 200 increases or is maximized. Further, since the cushion layer 250 alleviates the step difference of the micro pattern MP, deterioration of a luminance according to a position is prevented.

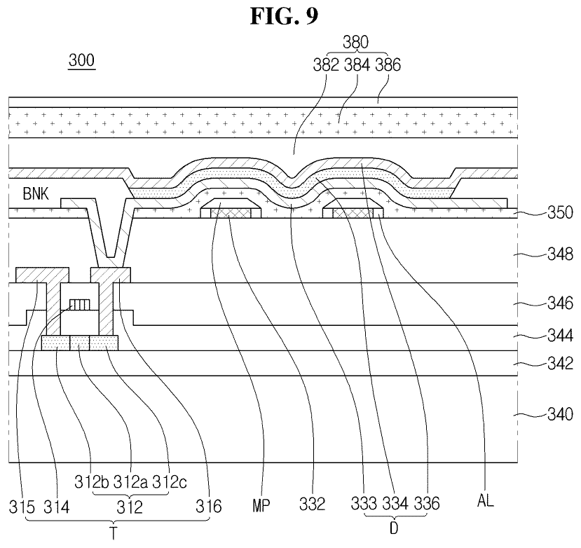

FIG. 9 is a cross-sectional view showing a display device according to a third embodiment of the present disclosure. Illustration on a part the same as that of first and second embodiments will be omitted, and a part different from that of first and second embodiments will be illustrated.

In FIG. 9, a thin film transistor T and a light emitting diode D are disposed on a substrate 340.

The thin film transistor T includes a semiconductor layer 312 on a buffer layer 342, a gate insulating layer 344 on the semiconductor layer 312, a gate electrode 314 on the gate insulating layer 344, an interlayer insulating layer 346 on the gate electrode 314, and source and drain electrodes 315 and 316 on the interlayer insulating layer 346.

The light emitting diode D includes a first electrode 333, an emitting layer 334, and a second electrode 336. The first electrode 333 may function as an anode of the light emitting diode D, and the second electrode 336 may function as a cathode of the light emitting diode D.

A bank layer BNK is disposed on the planarizing layer 348 and a boundary portion of the first electrode 333. At least one micro pattern MP is disposed on the planarizing layer 348 in an emission area EA surrounded by the bank layer BNK.

The micro pattern MP changes an incident angle of a light of the emitting layer 334 at interfaces among the first electrode 333, the cushion layer 350 and the planarizing layer 348 to at least reduce or minimize a total reflection and reduces a flatness of the interfaces among the first electrode 333, the cushion layer 350 and the planarizing layer 348 to prevent a surface plasmon polariton (SPP) mode.

A conductive pattern 332 is disposed under the micro pattern MP. The conductive pattern 332 may include a transparent conductive material such as indium tin oxide (ITO) and indium zinc oxide (IZO), and it is not limited thereto. The micro pattern MP has a slanting side surface, and a width of the conductive pattern 332 is smaller than a width of a bottom surface of the micro pattern MP. As a result, air layers AL are disposed at both sides of the conductive pattern 332 under the micro pattern MP.

In another embodiment, a width of the conductive pattern 332 may be the same as a width of a bottom surface of the micro pattern MP, and air layers AL may be omitted.

A cushion layer 350 is disposed on the planarizing layer 348 and the micro pattern MP. The cushion layer 350 covers the top surface of the planarizing layer 348 and the top and side surfaces of the micro pattern MP. The cushion layer 350 changes a structure of layers and an incident angle of a light at interfaces among the layers to at least reduce or minimize a total reflection in the display device 300.

The light emitting diode D is disposed on the cushion layer 350. Since the cushion layer 350 alleviates a step difference of the micro pattern MP, the first electrode 333 of the light emitting diode D has a uniform thickness throughout the entire substrate 340 and a current deviation according to a position is at least reduced or minimized.

The first electrode 333 of the light emitting diode D may be electrically connected to the drain electrode 316 of the thin film transistor T through a contact hole in the planarizing layer 348 and the cushion layer 350.

In the display device 300, since the anode has a single layer of the first electrode 333, a luminance deviation is reduced or minimized.

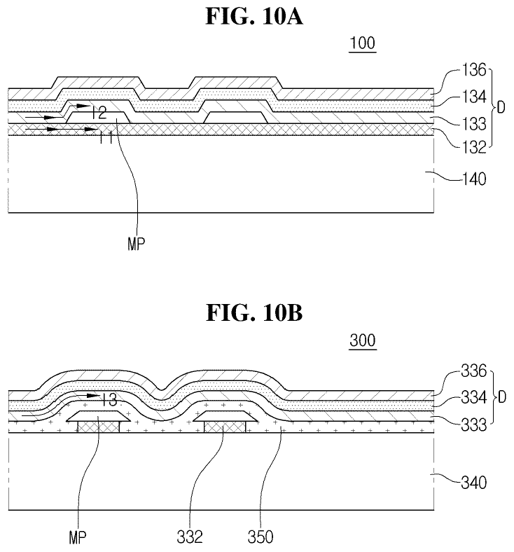

FIG. 10A is a cross-sectional view showing a micro pattern and a light emitting diode of a display device according to a first embodiment of the present disclosure, and FIG. 10B is a cross-sectional view showing a micro pattern and a light emitting diode of a display device according to a third embodiment of the present disclosure.

In FIG. 10A, the anode of the light emitting diode D includes the first electrode 132 and the second electrode 133, and the first electrode 132 and the second electrode 133 electrically contact each other in the display device 100 according to a first embodiment of the present disclosure.

As a result, a current supplied from the thin film transistor T includes a first current I1 flowing through the first electrode 132 and a second current I2 flowing through the second electrode 133. The first electrode 132 and the second electrode 133 are divided at the micro pattern MP. Since the first electrode 132 is disposed under the micro pattern MP and the second electrode 133 is disposed on the micro pattern MP, the current is divided into the first current I1 under the micro pattern MP and the second current I2 on the micro pattern MP.

Since only a portion (i.e., the second current I2) of the current is applied to the emitting layer 134 in a region over the micro pattern MP, a luminance of the light emitting diode D in the region over the micro pattern MP is reduced. As a result, a luminance deviation according to a position is generated due to a non-uniform current in the display device 100 according to a first embodiment of the present disclosure.

In FIG. 10B, the anode of the light emitting diode D includes the first electrode 333, and the conductive pattern 332 under the micro pattern MP is electrically insulated from the first electrode 333 in the display device 300 according to a third embodiment of the present disclosure. Since a current supplied from the thin film transistor T flows through the first electrode 333 as a third current I3, a uniform current is supplied to the emitting layer 334 throughout the entire substrate 340. As a result, a luminance deviation according to a position is reduced or prevented.

A method of fabricating a display device according to a third embodiment of the present disclosure will be illustrated.

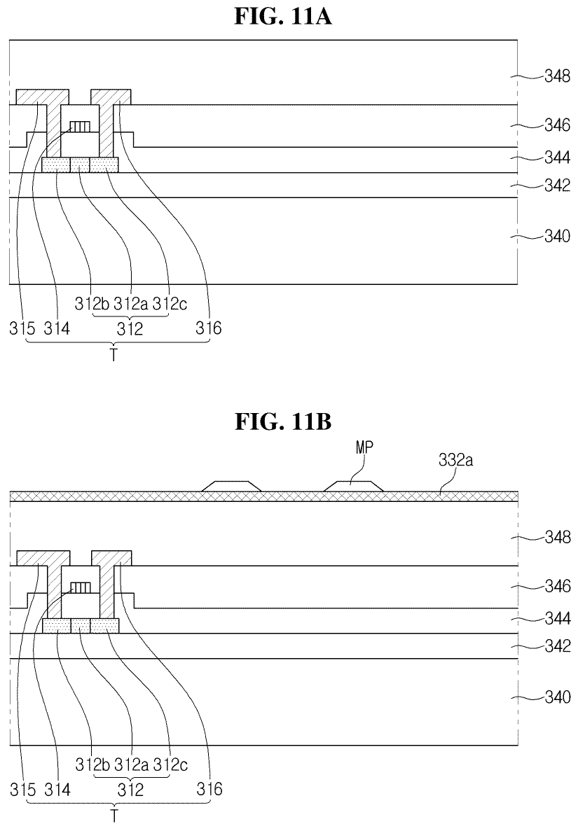

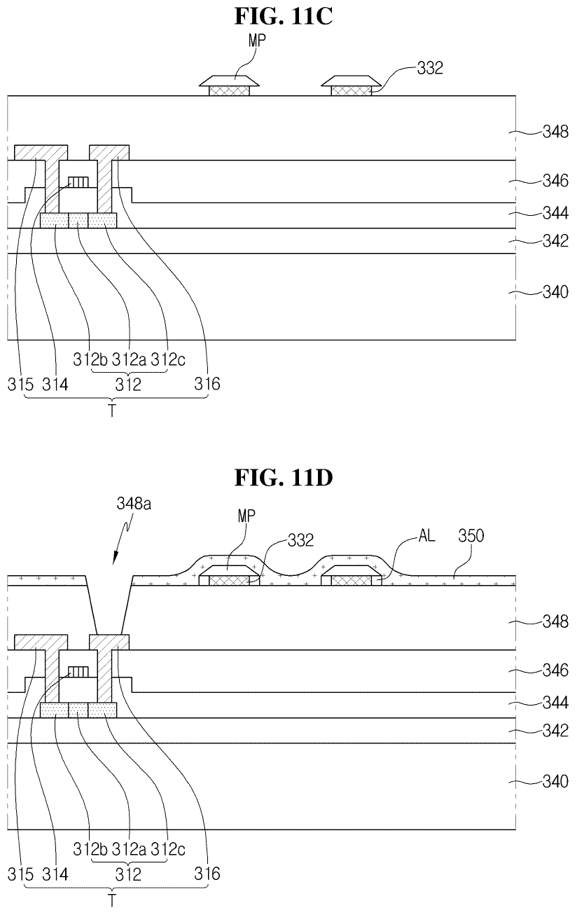

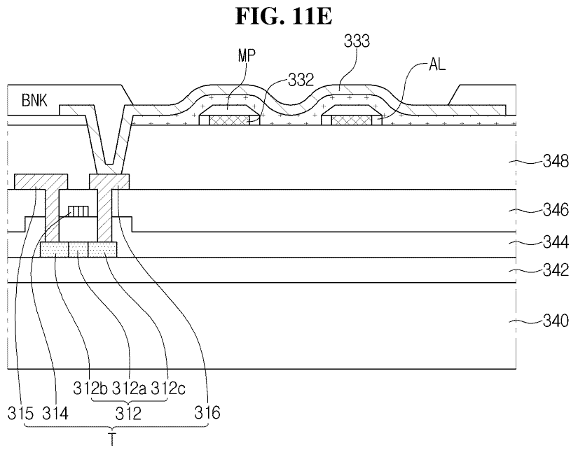

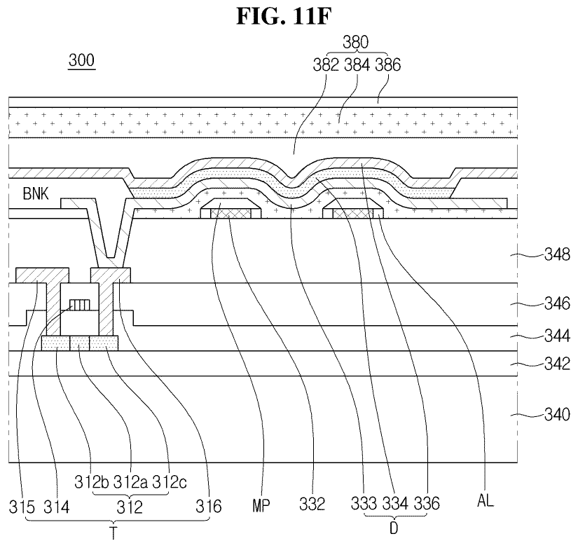

FIGS. 11A to 11F are cross-sectional views showing a method of fabricating a display device according to a third embodiment of the present disclosure.

In FIG. 11A, the buffer layer 342 is formed on the entire substrate 340. The substrate 340 may include a hard material such as a glass or a soft material such as a plastic material. The plastic material may include polyimide (PI), polymethylmethacrylate (PMMA), polyethylene terephthalate (PET), polyether sulfone (PES) and polycarbonate (PC). The buffer layer 342 may have a single layer or a multiple layer of an inorganic insulating material such as silicon nitride (SiNx) and silicon oxide (SiOx).

Next, the semiconductor layer 312 is formed on the buffer layer 342 by depositing and patterning a polycrystalline semiconductor material such as polycrystalline silicon or an oxide semiconductor material such as gallium zinc oxide (IGZO), indium zinc oxide (IZO), indium gallium tin oxide (IGTO) and indium gallium oxide (IGO).

Next, the gate insulating layer 344 is formed on the semiconductor layer 312 by depositing an inorganic insulating material such as silicon nitride (SiNx) and silicon oxide (SiOx). Next, the gate electrode 314 is formed on the gate insulating layer 344 by depositing and patterning a metallic material such as molybdenum (Mo), aluminum (Al), chromium (Cr), gold (Au), titanium (Ti), nickel (Ni), neodymium (Nd) and copper (Cu). For example, the metallic material may be deposited through a sputtering method, and the metallic material layer may be etched through a wet etching method.

Next, the interlayer insulating layer 346 is formed on the gate electrode 314 by depositing an organic insulating material such as photoacryl or an inorganic insulating material such as silicon nitride (SiNx) and silicon oxide (SiOx). Next, the source and drain electrodes 315 and 316 are formed on the interlayer insulating layer 346 by depositing and patterning a metallic material such as molybdenum (Mo), aluminum (Al), chromium (Cr), gold (Au), silver (Ag), tungsten (W), titanium (Ti), nickel (Ni), neodymium (Nd) and copper (Cu).

Next, the planarizing layer 348 is formed on the source and drain electrodes 315 and 316 by depositing at least one of an organic material and an inorganic material.

In FIG. 11B, after a conductive material layer 332a is formed on the planarizing layer 348 by depositing a transparent conductive material such as indium tin oxide (ITO) and indium zinc oxide (IZO), the micro pattern MP is formed on the conductive material layer 332a by depositing and patterning an inorganic material such as silicon nitride (SiNx) and silicon oxide (SiOx). The micro pattern MP has a slanting side surface.

The conductive material layer 332a functions as a blocking layer while the micro pattern MP is patterned. As a result, the damage of the planarizing layer 348 due to an etching gas is prevented while the micro pattern MP is patterned.

In FIG. 11C, the conductive pattern 332 is formed by patterning the conductive material layer 332a. The conductive material layer 332a may be isotropically etched such that side portions under the micro pattern MP are removed. As a result, the micro pattern MP and the conductive pattern 332 may have an overhang structure where the side surface of the micro pattern MP extends over the side surface of the conductive pattern 332.

In FIG. 11D, the cushion layer 350 is formed on the micro pattern MP by depositing an inorganic material such as silicon nitride (SiNx) and silicon oxide (SiOx). Since the cushion layer 350 is not formed in the side portions under the micro pattern MP having an overhang structure, the air layer AL is formed at both sides of the conductive pattern 332 under the micro pattern MP. Next, a contact hole 348a exposing the drain electrode 316 of the thin film transistor T is formed by patterning the planarizing layer 348 and the cushion layer 350.

In FIG. 11E, the first electrode 333 is formed on the cushion layer 350 by depositing and patterning a metallic material such as silver (Ag), aluminum (Al), gold (Au), molybdenum (Mo), tungsten (W), chromium (Cr) and an alloy thereof or a transparent conductive material such as indium tin oxide (ITO) and indium zinc oxide (IZO).

Next, the bank layer BNK is formed on the cushion layer 350 and the boundary portion of the first electrode 333 by depositing and patterning an inorganic insulating material such as silicon nitride (SiNx) and silicon oxide (SiNx), an organic insulating material such as benzocyclobutene (BCB), acrylic resin, epoxy resin, phenolic resin, polyamide resin and polyimide resin and a photosensitive material including a black pigment.

In FIG. 11F, after the emitting layer 334 is formed on the first electrode 333 by depositing an organic emitting material, the second electrode 336 is formed on the emitting layer 334 by depositing a metallic material or a transparent conductive material such as indium tin oxide (ITO) and indium zinc oxide (IZO).

Next, after the first encapsulating layer 382 is formed on the second electrode 336 by depositing an inorganic material, the second encapsulating layer 384 is formed on the first encapsulating layer 382 by depositing an organic material. Next, the third encapsulating layer 386 is formed on the second encapsulating layer 384 by depositing an inorganic material to complete the encapsulating layer 380.

Consequently, in the display device according to first to third embodiments of the present disclosure, since the micro pattern changes the incident angle of the light of the emitting layer at the interfaces among the layers, the total reflection is at least reduced or minimized. As a result, the light efficiency increases or is maximized.

Further, since the cushion layer on the micro pattern alleviates the step difference of the micro pattern to form the anode of the light emitting diode as the round shape, the anode has a uniform thickness. As a result, the current deviation according to a position is prevented, and the non-uniform luminance of the display device is prevented.

In addition, since the light efficiency is improved, the power consumption is reduced to obtain a low power driving.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device comprising:
a substrate including a plurality of subpixels;
a transistor in each of the plurality of subpixels;
a planarizing layer on the transistor;
a micro pattern on the planarizing layer in each of the plurality of subpixels;
a cushion layer on the micro pattern; and
a light emitting diode on the planarizing layer.

2. The display device of claim 1, wherein the micro pattern has a slanting side surface.

3. The display device of claim 1, wherein the light emitting diode comprises:
a first electrode between the planarizing layer and the micro pattern;
a second electrode on the cushion layer;
an emitting layer on the second electrode; and
a third electrode on the emitting layer.

4. The display device of claim 3, wherein the first electrode includes a transparent conductive material.

5. The display device of claim 1, wherein the light emitting diode comprises:
a first electrode on the cushion layer;
an emitting layer on the first electrode; and
a second electrode on the emitting layer.

6. The display device of claim 5, further comprising:
a conductive pattern between the planarizing layer and the micro pattern.

7. The display device of claim 6, wherein air layers are at both sides of the conductive pattern under the micro pattern.

8. The display device of claim 6, wherein the conductive pattern includes a transparent conductive material.

9. A display device comprising:
a substrate including a plurality of subpixels;
a transistor in each of the plurality of subpixels;
a planarizing layer on the transistor; and
a light emitting diode on the planarizing layer, the light emitting diode including an anode, an emitting layer, and a cathode,
wherein a top surface of the anode is formed as a curved surface.

10. The display device of claim 9, further comprising:
a micro pattern on the planarizing layer; and
a cushion layer on the micro pattern, the cushion layer having a top surface that has a round shape and the cushion layer alleviating a step difference of the micro pattern.

11. The display device of claim 10, wherein the anode is on the cushion layer.

12. The display device of claim 11, further comprising:
a conductive pattern between the planarizing layer and the micro pattern; and
air layers at both sides of the conductive pattern under the micro pattern.

13. The display device of claim 10, wherein the anode includes a first electrode on the planarizing layer and a second electrode on the cushion layer, and the micro pattern is between the first electrode and the cushion layer.
